(19) United States
(12) Patent Application Publication
(10) Pub. No.: US 2013/0098437 A1
(43) Pub. Date: Apr. 25, 2013

(54) Photovoltaic Cell Having a Structured Back Surface and Associated Manufacturing Method

(71) Applicants: Philippe Thony, Entre-Deux-Guiers (FR); Nicolas Chaix, Saint Martin D'Uriage (FR); Jean-Paul Garandet, Le Bourget Du Lac (FR)

(72) Inventors: Philippe Thony, Entre-Deux-Guiers (FR); Nicolas Chaix, Saint Martin D'Uriage (FR); Jean-Paul Garandet, Le Bourget Du Lac (FR)

(73) Assignee: Commissariat A L'Energie Atomique Et Aux Energies Alternatives, Paris (FR)

(21) Appl. No.: 13/695,449

(22) PCT Filed: May 3, 2011
(86) PCT No.: PCT/IB2011/051954

§ 371 Date: Jan. 10, 2013

(30) Foreign Application Priority Data
May 5, 2010 (FR) 10 01939

(51) Int. Cl. H01L 31/0216; H01L 31/0232

(52) U.S. Cl. CPC H01L 31/0216; H01L 31/0232
USPC 136/256; 438/72

(57) ABSTRACT

The invention relates to a photovoltaic cell (1) which includes at least one wafer (2) of a semi-conductor material, with a front surface (21) intended for receiving incident light and a back surface (22) opposite said front surface, as well as to methods for manufacturing said photovoltaic cell. The back surface (22) includes an electric contact (32) and a structure (4), referred to as an optical structure, which is discrete and capable of redirecting the incident light towards the core of the wafer.

The present invention relates to the field of photovoltaic cells.

These cells are generally formed from wafers of semi-conductive material, such as silicon, within which the photovoltaic conversion takes place.

The invention relates to a photovoltaic cell comprising at least one wafer of semi-conductive material and an electrical contact on the rear face of said wafer, the rear face being the face opposite the face through which the incident light enters.

The present invention also relates to a method for producing such a photovoltaic cell.

In order to reduce the fabrication costs of photovoltaic cells and, consequently, the costs of producing electricity with these cells, the manufacturers in the sector are seeking to increase their efficiency.

To this end, it has already been proposed to modify the optical propagation of the photons in the silicon wafer.

For example, it has been proposed to structure the geometry of the front face of the silicon wafer exposed to the incident light to modify its optical behavior. These optical structures may take the form of pyramidal structures, for which the angles of the planes of the pyramid correspond to crystalline axes of the silicon.

Such optical structures on the front face of the wafer have also been proposed for materials other than silicon. They may, for example, be surface roughnesses arranged more or less randomly.

The incident light passing through the front face of the wafer of semi-conductive material structured in this way is then deflected by virtue of this structuring, which increases the length of travel of a photon in the core of the wafer of semi-conductive material and, consequently, its probability of generating a photovoltaic phenomenon instead of reaching the unlit face of said wafer.

Until now, theoretical optical structures capable of enhancing the efficiency of the photovoltaic cell have mainly been proposed, without the possibility of fabricating them on an industrial scale.

This is because the formation of these structures on the front face of the semi-conductive material is badly controlled, in particular because the formation of the front electrical contact degrades these structures.

Consequently, there is no control over the real increase of the efficiency of a photovoltaic cell that can be obtained with these structures.

Structures capable of enhancing the efficiency of a photovoltaic cell have also been proposed on the rear face of the semi-conductive material.

The article “Efficiency enhancement in SI Solar cells by textured photonic crystal back reflector”, L. Zeng & al., Applied Physics Letters 89, 111111 (2006) can be cited as an example.

In this article, the rear face of the wafer of semi-conductive material is provided with a diffraction grating combined with a number of alternate layers of distinct materials forming a Bragg grating. With the implementation of these structures, the light arriving on the rear face of the wafer of semi-conductive material is reflected in a controlled manner toward the core of the wafer of semi-conductive material.

In order to highlight the performance levels obtained with these structures, the authors have proposed a comparison with a wafer of semi-conductive material whose rear face is provided only with a diffraction grating, with no Bragg grating. The optical structure is formed in the mass of the wafer of semi-conductive material.

All these optical structures do not make it possible to produce metallic contacts on this rear face with the methods known in the industry.

In practice, in this article, the diffraction grating is produced in the silicon forming the wafer of semi-conductive material. The electrical contact can then be obtained only by injecting metal into the patterns formed in the silicon, so that a bake performed at silicon/metal melting temperature would lead to the corruption of the patterns forming the diffraction grating. Moreover, when the structure includes a Bragg grating (produced by alternate Si/Si₃N₄ or Si/SiO₂ layers) covering the diffraction grating, nor can any electrical contact be produced because the Bragg grating would also be corrupted and could not exercise its function.

For this reason, the authors have moved the function normally provided by the rear electrical contact to the sides of the wafer of silicon.

This presents a problem when it comes to obtaining photovoltaic cells on an industrial scale, particularly for reasons of bulk.

It therefore appears that the idea of effecting a structuring of one of the front and/or rear faces of a wafer of semi-conductive material of the photovoltaic cell in order to enhance the efficiency of this cell has already been proposed.

However, the known technical solutions have proven difficult to control. Furthermore, their industrialization is difficult, or even incompatible with the production of a rear electrical contact.

In order to even further reduce the fabrication costs of the photovoltaic cells and consequently the costs of electricity production with these cells, the manufacturers of the sector are also seeking to reduce the thickness of the wafers of semi-conductive material employed in these cells, which are currently of the order of 180 μm.

To this end, the pathways that can currently be envisaged are detailed in “Crystalline Si solar cells and the microelectronics experience”, K. Baert & al., Solid State Technology (Internet), August 2009. Moreover, the projections made from these pathways that can theoretically be envisaged make it possible to anticipate the current thickness of 180 μm of a silicon wafer changing to a thickness of 120 μm in 2012, 80 μm in 2015 then 40 μm in 2020, while retaining, or even enhancing, the efficiency of the current photovoltaic cells.

In fact, the current photovoltaic cells generally make use of silicon wafers, which represent approximately 40% of the cost of a kilowatt hour produced by the cell. Thus, a reduction by a factor of two of the thickness of the silicon wafers would imply a reduction of 20% of the cost of the kilowatt hour produced by the cell.

Unfortunately, the reduction of the thickness of the silicon wafers is accompanied by a drop in the photovoltaic conversion efficiency. This is because, the more the thickness of a wafer is reduced, the more the probability that a photon of incident light passes through the entire thickness of the wafer without generating any photovoltaic phenomenon increases. The photons of the incident light that have passed through the wafer are transmitted by the rear face of the wafer and are reflected toward the core in an uncontrolled manner.

Thus, it has been proposed to associate a wafer of reduced thickness with optical structures as described previously, in order to reduce the fabrication costs while retaining an identical, even better, photovoltaic conversion efficiency.

Unfortunately, in this case also, the same difficulties associated with the placement of optical structures on the faces of the wafer of semi-conductive material arise.

One objective of the invention is thus to propose a photovoltaic cell that offers an opto-electrical conversion efficiency better than that of the existing photovoltaic cells.

Another objective of the invention is to propose a photovoltaic cell that has both a reduced thickness compared to the existing cells and an opto-electrical conversion efficiency that is identical to, or possibly better than, that of the existing cells.

To achieve at least one of these objectives, the invention proposes a photovoltaic cell comprising at least one wafer of semi-conductive material, with a front face intended to receive the incident light and a rear face, opposite said front face, characterized in that the rear face comprises an electrical contact and a structure, called optical structure, which is discrete and capable of redirecting the incident light toward the core of the wafer.

The photovoltaic cell will be able to provide other technical characteristics, taken alone or in combination:
the thickness of the wafer of semi-conductive material is between 10 μm and 200 μm, preferably between 10 μm and 180 μm, advantageously between 50 μm and 150 μm;
the optical structure exhibits a periodic structuring of patterns, these patterns thus forming a diffraction grating for the incident light;
the pitch of the patterns of the optical structure is between 300 nm and 2 μm, in both directions of the plane formed by the rear face of the wafer of semi-conductive material;
the width of the patterns of the optical structure is between 100 nm and 2 μm;
the height of the patterns of the optical structure is between 20 nm and 5 μm;
the patterns are in the form of lines, bump contacts or holes;
the electrical contact is produced with a material chosen by one of the following materials: aluminum, silver, copper, nickel, platinum, chromium, tungsten, carbon in nanotube form or transparent conductive oxide;
the optical structure is a material chosen from silica, silicon nitride, possibly hydrogen-enriched, silicon carbide, alumina, titanium dioxide, titanium nitride, magnesium fluoride, tantalum anhydride or graphite;
the optical structure is arranged between the wafer of semi-conductive material and the electrical contact;
the optical structure has an electrical contact function and a passivation layer covers said electrical contact;
the front face of the wafer of semi-conductive material also comprises an optical structure, for example formed by pyramidal structures for which the angles of the planes of the pyramid correspond to crystalline axes of the semi-conductive material or by surface roughnesses arranged more or less randomly.

To achieve at least one of these objectives, the invention also proposes a method for producing a photovoltaic cell comprising at least one wafer of semi-conductive material, with a front face intended to receive the incident light and a rear face, opposite said front face, characterized in that it comprises, from the wafer of semi-conductive material, the following steps:
(a) producing, on the rear face of the wafer, a structure, called optical structure, which is discrete and capable of redirecting the incident light toward the core of the wafer;
(b) depositing a layer of electrically conductive material, covering the optical structure and the rear face of the wafer;
(c) performing a bake of the assembly thus formed by the wafer of semi-conductive material, the optical structure and the layer of electrically conductive material at a temperature less than the melting temperature of the material forming the optical structure, in order to form an electrical contact between the layer of electrically conductive material and the wafer of semi-conductive material.

The method according to the invention will be able to provide other technical characteristics, taken alone or in combination:
the step (a) comprises the following steps:
   (a₁) deposition of a layer of resin on the wafer of semi-conductive material, on the rear face of the wafer of semi-conductive material;
   (a₂) lithographic printing of an inverse pattern in the layer of resin;
   (a₃) deposition of a layer of material exhibiting a melting temperature greater than the melting temperature of the material intended to be deposited in the step (b) and covering both the resin and the rear face of the wafer, in order to form said optical structure;
   (a₄) removal of the resin with the material deposited in the step (a₃) located on the resin.
the material forming the optical structure is chosen from an oxide of silicon, silicon nitride, silicon carbide, an oxide of aluminum or titanium dioxide.
there is provided, between the step (b) and the step (c), a step of positioning a pierced thermal screen on the layer of metal of the structure obtained on completion of the step (b), so that the piercings of the screen coincide with the gaps left between two patterns of the optical structure.

The invention also proposes an alternative method for producing a photovoltaic cell comprising at least one wafer of semi-conductive material, with a front face intended to receive the incident light and a rear face, opposite said front face, characterized in that it comprises, from the wafer of semi-conductive material, the following steps:
(a′) producing, on the rear face of the wafer, an optical structure filled with electrically conductive material, which is discrete and capable of redirecting the incident light toward the core of the wafer,
(b′) performing a bake of the assembly thus formed by the wafer of semi-conductive material and the optical structure filled with electrically conductive material in order to form an electrical contact between said material and the wafer of semi-conductive material;
(c′) depositing a passivation layer covering the optical structure filled with electrically conductive material and the rear face of the wafer.

The alternative method according to the invention will be able to provide other technical features:
the step (a′) comprises the following steps:
   (a′₁) deposition of a layer of resin on the rear face of the wafer of semi-conductive material;
   (a′₂) lithographic printing of an inverse pattern in the layer of resin;
   (a′₃) deposition of a layer of electrically conductive material covering both the resin and the rear face of the wafer, in order to form said optical structure;
   (a′₄) removal of the resin with the material deposited in the step (a₃) located on the resin.
there is provided, between the step (a′) and the step (b′), a step of positioning a pierced thermal screen on the optical structure of electrically conductive material of the structure obtained on completion of the step (a′), so that the piercings of the screen coincide with the gaps left between two patterns of the optical structure.

Finally, one or other of the methods according to the invention will be able to provide for the electrically conductive material to be chosen by one of the following materials: aluminum, silver, gold, copper, nickel, platinum, chromium or tungsten, carbon in nanotube form or transparent conductive oxide.

Other features, aims and advantages of the invention will emerge from the following detailed description given with reference to the following figures:

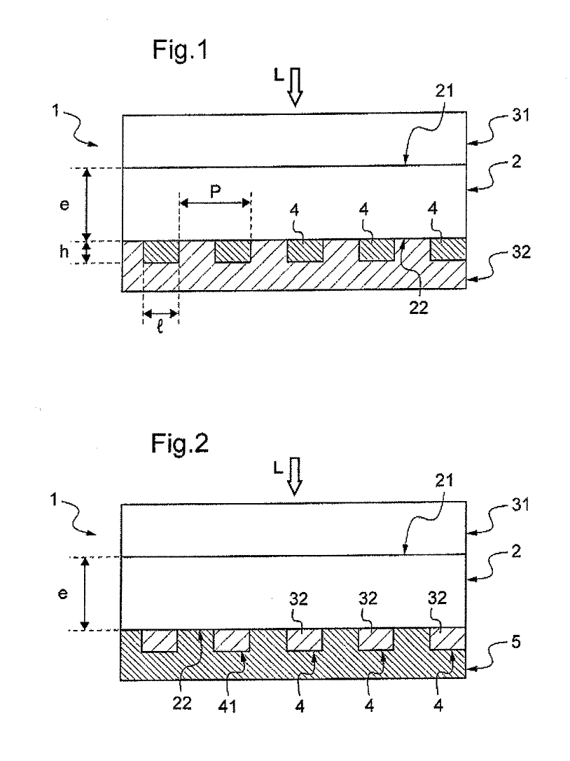

FIG. 1 is a diagram representing, in a cross-sectional view, a photovoltaic cell according to the invention;

FIG. 2 is a diagram representing, in a cross-sectional view, a variant of a photovoltaic cell according to the invention;

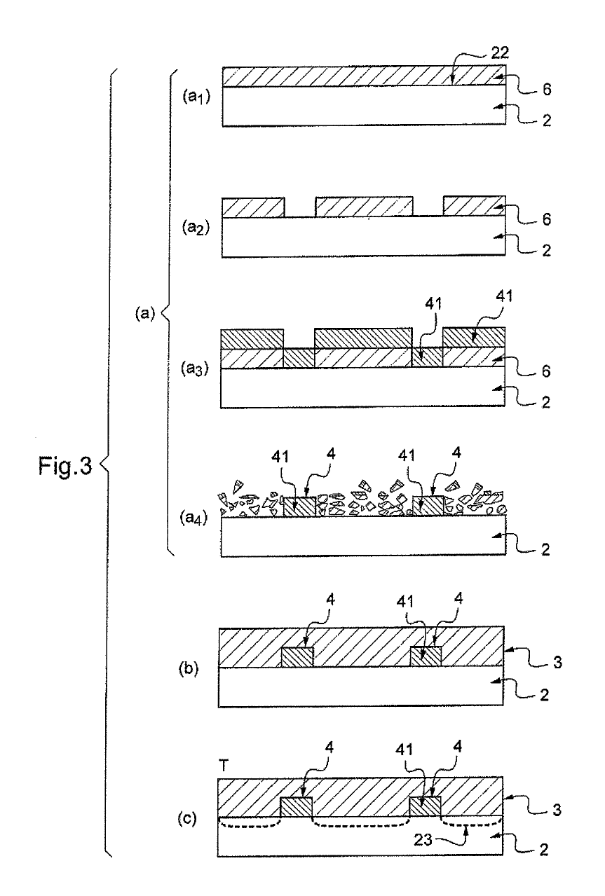

FIG. 3 represents the different steps of a method for producing the photovoltaic cell of FIG. 1;

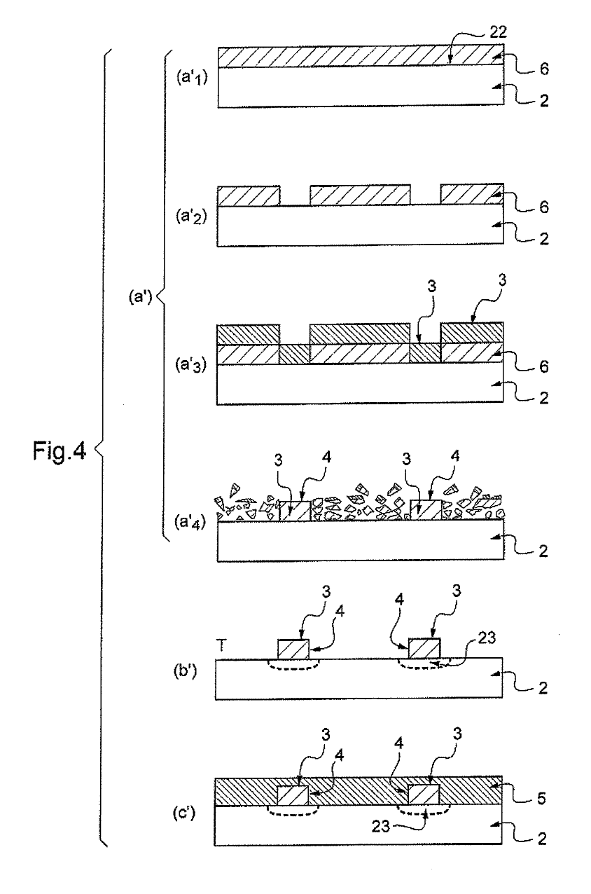

FIG. 4 represents the different steps of a method for producing the photovoltaic cell of FIG. 2.

The photovoltaic cell 1 comprises at least one wafer 2 of semi-conductive material, with a front face 21 intended to receive the incident light (represented by the arrow L in FIGS. 1 and 2) and a rear face 22, opposite said front face 21.

It also comprises an electrical contact 32 on the rear face 22 of the wafer 2 and an electrical contact 31 on the front face 21 of the wafer 2, generally in the form of a grid in order to allow the incident light to pass. The term “electrical contact” should be understood to mean the association of the material chosen to form the contact and the alloy region between said material and the wafer of semi-conductive material.

The rear face 22 comprises a structure, hereinafter called optical structure 4, which is discrete and capable of redirecting the incident light toward the core of the wafer.

The term “discrete structure” should be understood to mean a structure formed by independent patterns, so that the structure is discontinuous.

Preferably, this optical structure 4 is arranged so as to redirect the incident light at angles different to the rays of the incident light. The length of travel of a photon in the core of the wafer is thus increased. To this end, the optical structure 4 exhibits a periodic structuring of patterns 41, these patterns 41 thus forming a diffraction grating for the incident light.

The patterns 41 may be arranged in the form of lines, bump contacts or even holes.

These lines or these bump contacts may have various forms depending on the nature of the fabrication method. Thus, they may have a profile (transversal section) that is rectangular, triangular or even rounded, or even semicircular.

The pitch P of the patterns 41, that is to say the distance between two patterns, is between 300 nm and 2 μm, in both directions of the plane formed by the rear face 22 of the wafer 2 of semi-conductive material. The width of these patterns is between 10 nm and 2 μm. Finally, the height of these patterns is between 20 nm and 5 μm.

For example, a pattern 41 may have a height h of 100 nm and a width 1 of 40 nm. The pitch P between two patterns can be 1 μm. The applicant was able, after having produced these patterns on the rear face of a wafer of silicon and deposited a layer of aluminum to form the electrical contact, to determine a reflection coefficient of 38% for the order zero and of 62% for the higher orders.

The cell represented in FIG. 1 comprises an optical structure 4 distinct from the electrical contact 32. The optical structure 4 is arranged between the wafer of semi-conductive material 2 and the electrical contact 32.

The material chosen to form the electrical contact 32 can be taken from one of the following metals: aluminum (Al), silver (Ag), gold (Au), copper (Cu), nickel (Ni), platinum (Pt), chromium (Cr) or tungsten (W). The electrical contact 32 is then a metal contact.

As a variant, this material may be a non-metallic material, but still a conductor of electricity, such as carbon nanotubes or transparent conductive oxides (better known by the acronym TCO).

The optical structure 4 is made of a material chosen from an oxide of silicon, silicon nitride, silicon carbide, an oxide of aluminum (alumina) or titanium dioxide, all of which can be amorphous or crystalline, perfectly stoichiometric or not, perfectly pure or not. It is also possible to use, for this optical structure 4, titanium nitride (TiN), magnesium fluoride (MgF₂), tantalum anhydride (Ta₂O₅), graphite or porous silicon.

These materials are physically stable at temperatures greater than the usual bake temperatures. The bake temperatures generally used in the fabrication of photovoltaic cells are less than or equal to 900° C. (these materials are obviously also chemically stable up to that temperature).

More generally, a material that is physically stable up to at least 900° C., even at the interface with another material likely to create a eutectic, will be chosen to form the optical structure 4. This material will therefore remain in solid phase up to this temperature, including at the abovementioned interfaces.

Because of this, the optical structure 4 cannot be eliminated, or even corrupted during a bake.

These materials also have the advantage of not creating recombinant defects at the interface with the wafer of semi-conductive material 2, which is, for example, made of silicon.

A photovoltaic cell 1 that conforms to the invention will be able, for example, to comprise a wafer 2 of silicon, an optical structure 4 of silicon dioxide, and an electrical contact 32 produced with aluminum.

In this case, the bake can be performed at the eutectic temperature between aluminum and silicon, namely approximately 577° C., the SiO₂ remaining in solid phase at this temperature, at the SiO₂/Al interface, at the SiO₂/Si interface, and at the very core of the SiO₂.

The melting of the aluminum with the silicon does not then involve altering the optical structure of silicon dioxide. Reference can be made to FIG. 3 where an alloy region 23 is represented between the metal and the wafer of semi-conductive material.

Other associations of the materials mentioned above can obviously be envisaged.

To give another nonlimiting example, the photovoltaic cell 1 may comprise a wafer 2 of silicon, an optical structure 4 of titanium nitride and an electrical contact of copper.

As a variant, and as represented in FIG. 2, the optical structure 4 is formed by the electrical contact 32.

In this case, the electrical contact 32 takes the form of discrete patterns arranged on the rear face 22 of the wafer of semi-conductive material 2.

The material chosen to form the electrical contact 32 can be taken from one of the following metals: aluminum (Al), silver (Ag), gold (Au), copper (Cu), nickel (Ni), platinum (Pt), chromium (Cr) or tungsten (W). The electrical contact 32 then forms a metal contact.

As a variant, this material may be a non-metallic material, but still a conductor of electricity, such as carbon nanotubes or transparent conductive oxides.

In this case also, there is provided a layer made of a material that is not a conductor of electricity, called passivation layer 5, covering the electrical contact 32 forming the optical structure 4. This passivation layer 5 also comes into contact with the rear face 22 of the wafer of semi-conductive material 2, between the patterns 41 of the optical structure 4.

This passivation layer 5 can be made of silicon nitride, possibly hydrogenated or else of silicon oxide, silicon nitride, silicon carbide, aluminum oxide (alumina) or of titanium dioxide.

Here again, the material forming the electrical contact of the rear face 22 can be chosen, in a non-exhaustive manner, from one of the following metals: aluminum, silver, gold, copper, nickel, platinum, chromium or tungsten. It can also be chosen from non-metallic but electrically conductive materials, such as carbon nanotubes or transparent conductive oxides.

Moreover, the front face 21 of the wafer of semi-conductive material 2 may also comprise an optical structure (not represented) in order to further enhance the photovoltaic conversion efficiency of the cell 1. For example, this additional optical structure will be able to be formed by pyramidal structures for which the angles of the planes of the pyramid correspond to crystalline axes of the semi-conductive material 2 or by surface roughnesses arranged more or less randomly.

For all the structures represented in FIGS. 1 and 2, the thickness e of the wafer of semi-conductive material 2 will be able to be that of the existing wafers, that is to say 180 μm to 200 μm.

As a variant, this thickness e may be strictly less than 180 μm. More specifically, the thickness e of the wafer of semi-conductive material 2 may be strictly less than 180 μm while being greater than or equal to 10 μm. For example, this thickness e may be between 50 μm and 150 μm.

The methods for producing the photovoltaic cells of FIGS. 1 and 2 are represented in FIGS. 3 and 4 respectively, except for the step of forming the electrical contact 31 on the front face 21 of the wafer of semi-conductive material.

All of the method resulting in the photovoltaic cell of FIG. 1 is represented in FIG. 3.

To produce the photovoltaic cell represented in FIG. 1, the following method is employed from the wafer of semi-conductive material 2:
(a) the optical structure 4, which is discrete and capable of redirecting the incident light toward the core of the wafer 2, is produced on the rear face 22 of the wafer 2;
(b) a layer of electrically conductive material 3 is deposited covering the optical structure 4 and the rear face 22 of the wafer 2;
(c) the assembly thus formed by the wafer of semi-conductive material 2, the optical structure 4 and the layer of electrically conductive material 3 is baked at a temperature less than the melting temperature of the material forming the optical structure 4, in order to form the electrical contact 32 between the layer of electrically conductive material 3 and the wafer of semi-conductive material 2.

In order to obtain the photovoltaic cell represented in FIG. 1, the step (a) can be carried out by a method known as “lift-off”. In this case, the step (a) comprises the following steps:
(a₁) deposition of a layer of resin 6 on the rear face 22 of the wafer 2 of semi-conductive material;
(a₂) lithographic printing of an inverse pattern in the layer of resin 6;
(a₃) deposition of a layer of material 41 exhibiting a melting temperature greater than the melting temperature of the electrically conductive material intended to be deposited in the step (b) and covering both the resin and the rear face of the wafer, in order to form said optical structure;
(a₄) removal of the resin with the material deposited on the resin in the step (a₃). Only the material deposited on the rear face itself then remains.

It should be noted that the thickness of the layer deposited in the step (a₃) can be controlled, for example by controlling the duration of the deposition. In practice, depending on its thickness, the optical structure 4 may allow or not a diffusion of ion elements in the semi-conductive material 2, for example of silicon. Such is the case when the material intended to be deposited in the step (b) is a metal: the ion elements are then metal ions originating from the metal layer and passing through the optical structure 4.

During operation, this reinforces the field effect repelling the electrical charges that are generated by the photovoltaic conversion and have to be extracted through the front face, far from the rear face 22 of the wafer 2 where the recombinant defects, which are traps for these electrical charges, are situated. In fact, at the interfaces, there are still so-called recombinant defects which trap the free electrical charges.

The step (b) can be performed by a vacuum evaporation, by ion beam sputtering or by other techniques known to the person skilled in the art.

The bake step (c) reveals an alloy region 23 between the semi-conductive material of the wafer 2, for example silicon, and the material 3, for example a metal such as aluminum.

The form of the patterns 41 of the optical structure 4 is not affected by this bake step (c), so that, unlike notably the teachings of document D1, this step does not modify the optical properties expected of this optical structure 4.

It is possible to localize the bake by positioning, prior to the implementation of the step (c), a pierced thermal screen (not represented) on the metal layer 3 of the structure obtained on completion of the step (b). The positioning of the pierced thermal screen is such that the piercings thereof coincide with the gaps left between two patterns 41 of the optical structure 4, the screen then coinciding with the patterns 41 of the optical structure 4.

Thus, during the bake, the thermal screen makes it possible to modulate the temperature distribution over the structure. In the areas of contact with the screen, the wafer of semi-conductive material 2 will be locally less hot than in the piercing areas. The eutectic melting point is thus more rapidly reached in the piercing areas of the screen and the areas of the metal in contact with the screen are not transformed.

During subsequent fabrication steps, it is then necessary to take account of this fact, for example by protecting the rear face during impurity diffusion steps, in order to avoid doping this region.

The use of a thermal screen is particularly advantageous if the bake is performed in a lamp oven, for example.

The alloy region, notably in the case of a silicon/aluminum alloy, has the advantage of creating a field effect repelling the electrical charges generated, in use, by the photovoltaic conversion far from the rear face 22 of the wafer 2 where the recombinant defects are located.

For example, in the case of an electrical contact 32 produced with aluminum and a wafer 2 of silicon, the bake can be performed at the eutectic melting temperature, namely of the order of 577° C. At this temperature, the material forming the optical structure 4 is physically (and chemically) stable.

The duration of the bake is notably optimized with a view to the desired optical function: reflection coefficient on the rear face, diffraction efficiency.

The whole of the method leading to the photovoltaic cell of FIG. 2 is represented in FIG. 4.

To produce the photovoltaic cell represented in FIG. 2, the following method is employed from the wafer of semi-conductive material 2:
(a′) an optical structure 4 made of an electrically conductive material 3, which is discrete and capable of redirecting the incident light toward the core of the wafer 2, is produced on the rear face 22 of the wafer 2;
(b′) the assembly formed by the wafer of semi-conductive material 2 and the optical structure 4 filled with electrically conductive material is baked, in order to form the electrical contact 32 between the electrically conductive material 3 and the wafer of semi-conductive material 2.
(c′) a passivation layer 5 is deposited covering the optical structure 4 filled with the electrically conductive material and the rear face 22 of the wafer 2.

In order to obtain the photovoltaic cell represented in FIG. 2, the step (a′) can be performed by the “lift-off” method. In this case, the step (a) comprises the following steps:
(a′₁) deposition of a layer of resin on the rear face of the wafer of semi-conductive material;
(a′₂) lithographic printing of an inverse pattern in the layer of resin;
(a′₃) deposition of a layer of electrically conductive material covering both the resin and the rear face of the wafer, in order to form said optical structure;
(a′₄) removal of the resin with the material deposited on the resin in the step (a₃). Only the material deposited on the rear face 22 itself then remains.

The step (a′₃) can be performed by a vacuum evaporation, by ion beam sputtering or by other techniques known to the person skilled in the art.

Moreover, the bake step (b′) reveals an alloy region 23 between the semi-conductive material of the wafer 2, for example silicon, and the electrical contact 32, for example produced with aluminum with the passivation properties that devolve therefrom. In the case of an electrical contact produced with aluminum on a silicon wafer, the bake can be performed at the eutectic melting temperature, namely of the order of 577° C.

Here again, the form of the patterns 41 of the optical structure 4 is not affected by this bake step (b′), so that, unlike notably the teachings of the document D1, this step does not modify the optical properties expected of this optical structure 4.

It is possible to localize the bake at the pattern level. For this, it is possible, prior to the implementation of the step (b′), to position a pierced thermal screen (not represented) above the optical structure of electrically conductive material 3 obtained on completion of the step (a′). The positioning of the pierced thermal screen is such that the piercings thereof coincide with the patterns of the optical structure 4, the screen then coinciding with the gaps between the patterns 41 of the optical structure 4.

Thus, during the bake, the thermal screen makes it possible to modulate the temperature distribution over the structure. In the areas of contact with the screen, the wafer of semi-conductive material 2 will be locally less hot than in the piercing areas. The eutectic melting point is thus more rapidly reached in the piercing areas of the screen, that is to say at the pattern level, and the areas of the wafer of semi-conductive material in contact with the screen are not transformed.

During subsequent fabrication steps, it is then necessary to take account of this fact, for example by protecting the rear face during impurity diffusion steps, in order to avoid doping this region.

The use of a thermal screen is particularly advantageous if the bake is performed in a lamp oven, for example.

The step (c′) consisting in depositing a passivation layer can be performed by chemical vapor phase deposition, possibly plasma-assisted.

Whatever the production methods envisaged, an additional step aiming to enhance the passivation can be envisaged, for example by hydrogenation.

The lithographic printing steps implemented in the different production methods above can be performed by laser lithography, interference lithography which are likely to work well on non-planar surfaces, exhibiting not inconsiderable flatness defects, that is to say greater than 0.1 μm in height. These flatness defects are more generally between 0.1 μm and 10 μm in height.

It is also possible to employ other lithographic methods, by having first smoothed, for example by chemical means, the surface to be lithographically printed. These different techniques are known to the person skilled in the art.

1. A photovoltaic cell comprising at least one wafer of semi-conductive material, with a front face (21) configured to receive the incident light and a rear face, opposite said front face, wherein the rear face comprises an electrical contact and an optical structure, which is discrete and capable of redirecting the incident light toward the core of the wafer, said optical structure being made of an oxide of silicon, silicon nitride, possibly hydrogen-enriched, silicon carbide, alumina an oxide of aluminum, titanium dioxide, titanium nitride, magnesium fluoride, tantalum anhydride, graphite or porous silicon.

2. The photovoltaic cell as claimed in claim 1, in which the thickness of the wafer of semi-conductive material is between 10 μm and 200 μm.

3. The photovoltaic cell as claimed in claim 1, in which the optical structure exhibits a periodic structuring of patterns, these patterns thus forming a diffraction grating for the incident light.

4. The photovoltaic cell as claimed in claim 3, in which the pitch of the patterns of the optical structure is between 300 nm and 2 μm, in both directions of the plane formed by the rear face of the wafer of semi-conductive material.

5. The photovoltaic cell as claimed in claim 3, in which the width of the patterns of the optical structure is between 100 nm and 2 μm.

6. The photovoltaic cell as claimed in claim 3, in which the height of the patterns of the optical structure is between 20 nm and 5 μm.

7. The photovoltaic cell as claimed in claim 3, in which the patterns are in the form of lines, bump contacts or holes.

8. The photovoltaic cell as claimed in claim 1, in which the electrical contact is produced with a material chosen by one of the following materials: aluminum, silver, copper, nickel, platinum, chromium, tungsten, carbon in nanotube form or transparent conductive oxide.

9. The photovoltaic cell as claimed in claim 1, in which the optical structure is arranged between the wafer of semi-conductive material and the electrical contact.

10. The photovoltaic cell as claimed in claim 1, in which the front face of the wafer of semi-conductive material also comprises an optical structure formed by pyramidal structures for which the angles of the planes of the pyramid correspond to crystalline axes of the semi-conductive material or by surface roughnesses arranged more or less randomly.

11. A method for producing a photovoltaic cell comprising at least one wafer of semi-conductive material, with a front face configured to receive the incident light and a rear face, opposite said front face, wherein the method comprises, from the wafer of semi-conductive material, the following steps:
(a) producing, on the rear face of the wafer, an optical structure (4) which is discrete and capable of redirecting the incident light toward the core of the wafer, with a material comprising silica, an oxide of silicon, silicon nitride, possibly hydrogen-enriched, silicon carbide, alumina an oxide of aluminum, titanium dioxide, titanium nitride, magnesium fluoride, tantalum anhydride, graphite or porous silicon;
(b) depositing a layer of electrically conductive material, covering the optical structure and the rear face of the wafer;
(c) performing a bake of the assembly thus formed by the wafer of semi-conductive material, the optical structure and the layer of electrically conductive material at a temperature less than the melting temperature of the material forming the optical structure, in order to form an electrical contact between the layer of electrically conductive material and the wafer of semi-conductive material.

12. The method as claimed in claim 11, in which the step (a) comprises the following steps:
(a₁) deposition of a layer of resin on the wafer of semi-conductive material, on the rear face of the wafer of semi-conductive material;
(a₂) lithographic printing of an inverse pattern in the layer of resin;
(a₃) deposition of a layer of material exhibiting a melting temperature greater than the melting temperature of the material intended to be deposited in the step (b) and covering both the resin and the rear face of the wafer, in order to form said optical structure;
(a₄) removal of the resin with the material deposited in the step (a₃) located on the resin.

13. The method as claimed in claim one of claims 11, in which there is provided, between the step (b) and the step (c), a step of positioning a pierced thermal screen on the layer of electrically conductive material of the structure obtained on completion of the step (b), so that the piercings of the screen coincide with gaps left between two patterns of the optical structure.

14. The method as claimed in claim 11, in which the electrically conductive material comprises aluminum, silver, gold, copper, nickel, platinum, chromium or tungsten, carbon in nanotube form or transparent conductive oxide.

15. The photovoltaic cell as claimed in claim 1, in which the thickness of the wafer of semi-conductive material is between 10 μm and 180 μm.

16. The photovoltaic cell as claimed in claim 1, in which the thickness of the wafer of semi-conductive material is between 50 μm and 150 μm.
